(19) United States
(12) Patent Application Publication
(10) Pub. No.: US 2017/0282743 A1
(43) Pub. Date: Oct. 5, 2017

(54) SYSTEM AND METHOD FOR CONTROLLING VOLTAGE

(71) Applicant: MANDO CORPORATION, Gyeonggi-do (KR)

(72) Inventor: Yu-Tae KIM, Gyeonggi-do (KR)

(21) Appl. No.: 15/480,324

(22) Filed: Apr. 5, 2017

(30) Foreign Application Priority Data
Apr. 5, 2016 (KR) 10-2016-0041764

(51) Int. Cl. B60L 11/18; B60K 35/00; B60L 15/20

(52) U.S. Cl. CPC B60L 11/1861; B60L 15/2045; B60K 35/00

(57) ABSTRACT

Disclosed are a system and method for controlling a voltage. The system includes a battery voltage measurer configured to measure a voltage of a battery of a vehicle, a sensor driver configured to supply a voltage applied from the battery to various sensors included in the vehicle, and a controller configured to decrease or increase the voltage applied form the battery to secure a required voltage value required by the sensor driver.

### CROSS-REFERENCE TO RELATED APPLICATION

This application claims the benefit of Korean Patent Application No. 2016-00041764, filed on Apr. 05, 2016 in the Korean Intellectual Property Office, the disclosure of which is incorporated herein by reference.

### BACKGROUND

### 1.Field

Embodiments of the present disclosure relate to a system and method for controlling a voltage, and more particularly, to a system and method for controlling a voltage capable of supplying a constant voltage required for a sensor used in a vehicle.

### 2. Description of the Related Art

In general, the voltage of a battery mounted on a vehicle varies depending on the state of the vehicle.

However, an Electronic Control Unit (ECU) included in the vehicle may be operated correctly only by securing a voltage value corresponding to a rated voltage of the sensor from the battery.

For example, when the vehicle performs a braking control, the electronic control unit calculates a control pressure needed to performing an appropriate braking control based on sensor values measured from a wheel speed sensor and a wheel pressure sensor, etc.

At this time, the sensor values obtained by the wheel speed sensor, the wheel pressure sensor, etc. may have an accurate sensor value by securing a voltage value matching a rated voltage of the sensor from the battery.

However, conventionally, the voltage value applied from the battery varies according to the state of the vehicle and fluctuates.

At this time, when a voltage higher than the rated voltage of the sensor is applied, for example, a voltage value matching the rated voltage of the sensor may be secured by performing a step-down voltage control by using a regulator. However, when a voltage lower than the rated voltage of the sensor is applied, the sensor operation is complicated, so that the senor may not normally operate such as ignoring the input voltage.

### SUMMARY

Therefore, it is an aspect of the present disclosure to keep a voltage value supplied from a battery at a constant value in order to secure a voltage value matching a rated voltage of a sensor.

It is another aspect of the present disclosure to provide a control system for performing voltage control, which is used in a simultaneous manner in various sensors so that the production cost is reduced.

In accordance with one aspect of the present invention, a voltage control system of a vehicle, the voltage control system may comprise a battery voltage measurer configured to measure a voltage of a battery of a vehicle; a sensor driver configured to supply a voltage applied from the battery to various sensors included in the vehicle; and a controller configured to decrease or increase the voltage applied from the battery to secure a required voltage value required by the sensor driver.

The controller may further comprise a voltage decreasing circuit configured to decrease the voltage applied from the battery; a voltage increasing circuit configured to increase the voltage applied from the battery; and a noise filter configured to remove noise of a voltage passing through at least of the voltage increasing circuit and the voltage decreasing circuit.

In accordance with another aspect of the present invention, a method of controlling a voltage of a vehicle, the method may comprise measuring a voltage of a battery of the vehicle; comparing the measured voltage of the battery with a required voltage required by a sensor; and securing the required voltage by increasing or decreasing the voltage applied from the battery;

The wherein the securing of the required voltage by increasing or decreasing the voltage applied from the battery may include increasing the applied voltage when the applied voltage is higher than the required voltage, or decreasing the applied voltage when the applied voltage is lower than the required voltage; and removing noise of at least of the decreased applied voltage and the increased applied voltage.

In accordance with one aspect of the present invention, a system for controlling a voltage of a vehicle, the system may comprise a battery; a battery voltage measurer configured to measure a battery voltage of the battery of a vehicle; at least one sensor included in the vehicle; a controller configured to receive a rated voltage from the at least one sensor and decrease a battery voltage applied from the battery when a measurement of the applied battery voltage is higher than the rated voltage, and increase a battery voltage applied from the battery when a measurement of the applied battery voltage is lower than the rated voltage; and a sensor driver configured to output the increased battery voltage or the decreased battery voltage to the at least one sensor.

The controller may further comprise a voltage decreasing circuit configured to decrease the battery voltage; a voltage increasing circuit configured to increase the battery voltage; and a noise filter configured to remove noise from a voltage passing through at least of the voltage increasing circuit and the voltage decreasing circuit.

In accordance with the other aspect of the present invention, A method for controlling a voltage of a vehicle, the method may comprise: measuring a battery voltage of a vehicle; receiving a rated voltage from at least one sensor included in the vehicle; decreasing the battery voltage when a measurement of the battery voltage is higher than the rated voltage and increasing the battery voltage when a measurement of the battery voltage is lower than the rated voltage; and outputting the increased battery voltage or the decreased battery voltage to the at least one sensor.

The decreasing or increasing of the battery voltage may comprise removing noise from the decreased battery voltage or the increased battery voltage.

### BRIEF DESCRIPTION OF THE DRAWINGS

These and/or other aspects of the disclosure will become apparent and more readily appreciated from the following description of the embodiments, taken in conjunction with the accompanying drawings of which:

FIG. 1 is a block diagram illustrating various electronic devices included in a vehicle that includes a voltage control system in accordance with a first embodiment of the present disclosure.

FIG. 2 is a block diagram illustrating a voltage control system in accordance with the first embodiment of the present disclosure.

FIG. 3 is a flow-chart showing a voltage control method in accordance with the first embodiment of the present disclosure.

FIG. 4 is a block diagram illustrating a voltage control system in accordance with a second embodiment of the present disclosure.

FIG. 5 is a flowchart showing a voltage control method in accordance with the second embodiment of the present disclosure.

### DETAILED DESCRIPTION

Hereinafter, exemplary embodiments of the present disclosure will be described in detail with reference to the accompanying drawings. The exemplary embodiments described below are provided as examples to sufficiently transfer the spirits of the disclosure to those skilled in the art. Accordingly, the present disclosure is not limited to those embodiments described below and may be embodied in different forms. In addition, respective descriptions of well-known functions and constructions may be omitted for increased clarity and conciseness.

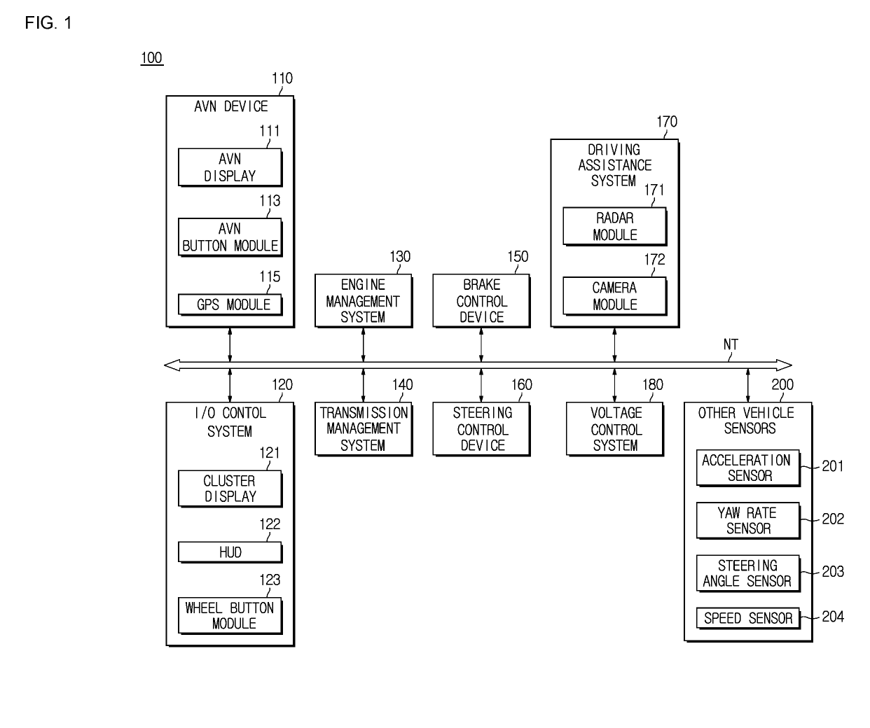

FIG. 1 is a block diagram illustrating various electronic devices included in a vehicle that includes a voltage control system in accordance with a first embodiment of the present disclosure.

A vehicle 1 may include a variety of electronic devices 100.

Specifically, as illustrated in FIG. 1, the vehicle (1) may include an Audio/Video/Navigation (AVN) device 110, an Input/Output (I/O) control system 120, an Engine Management system (EMS) 130, a transmission Management System (TMS) 140, a brake control device (brake-by-wire) 150, a steering control device (steering-by-wire) 160, a driving assistance system 170, a voltage control system 180, and vehicle sensors 200.

However, the electronic devices 100 shown in FIG. 1 is only a part of the electronic devices included in the vehicle 1, and the vehicle 1 may include more various electronic devices.

Also, the electronic devices 100 included in the vehicle 1 may send and receive data via a vehicle communication network (NT). The vehicle communication network (NT) may employ a communication standard, e.g. Media Oriented Systems Transport (MOST) having a maximum communication speed of 24.5 (Mega-bits per second) Mbps, FlexRay having a maximum communication speed of 10 Mbps, Controller Area Network (CAN) having a communication speed of 125 (kilo-bits per second) kbps to 1 Mbps, and Local Interconnect Network (LIN) having a communication speed of 20 kbps. The vehicle communication network (NT) may employ not only a single communication standard, e.g. MOST, FlexRay, CAN, and LIN, but also may employ a plurality of communication standards

The AVN device 110 is a device that outputs music or an image according to a control command of a driver. Specifically, the AVN device 110 may play a music or video according to a control command of the driver, and may guide a route to a destination received from a navigation system(not shown).

The AVN device 110 includes an AVN display 111 that displays an image to a driver, an AVN button module 113 that receives a control command of a driver, and a Global Positioning Sensor (GPS) module 115 that acquires geographical position information of the vehicle 1. Here, the AVN display 111 may use a touch-sensitive display (e.g., a touch screen) capable of receiving a touch input of a driver. Also, the AVN display 111 may use a liquid crystal display (LCD) panel or an organic light emitting diode (OLED) panel.

Also, the GPS module 115 receives information for calculating the position of the vehicle 1 from a Global Positioning System (GPS) satellite and determines the position of the vehicle 1 based on the information received from the GPS satellite.

An Input/Output (I/O) control system 120 receives a driver's control command via a button and displays information corresponding to the driver's control command. The input/Output control system 120 may include a cluster display 121 provided on a dashboard to display an image, a head-up display (HUD) 122 that projects an image on a wind screen, and a wheel button module 123 installed on a steering wheel.

The cluster display 121 is provided on the dashboard to display images. The cluster display 121 is provided adjacent to a windscreen so that a driver (U) may be informed of operation information of the vehicle 1, information of a road or a traveling route of the vehicle 1, in a state in which the sight line of the driver does not deviate greatly from the front of the driver 1. The cluster display 121 may be provided using a liquid crystal display (LCD) panel or an organic light emitting diode (OLED) panel.

The HUD 122 may project an image onto the windscreen. Specifically, the image projected on the windscreen by the HUD 122 may include operation information of the vehicle 1, road information or a travel path, etc., and may guide or alert the user to the location information based on information received from the navigation system.

The engine control system 130 may perform a fuel injection control, a fuel efficiency feedback control, a lean combustion control, an ignition timing control and an idling speed control. The engine control system 130 may be a single device or may be a plurality of devices connected through a communication.

The transmission control system 140 may perform a transmission control, a damper clutch control, a pressure control when a friction clutch is turned on/off and an engine torque control during shifting. The transmission control system 140 may be a single device or may be a plurality of devices connected through a communication.

The brake control device 150 may control the braking of the vehicle 1, and a representative example of the brake control device 150 may include an anti-lock brake system (ABS).

The steering control device 160 assists the steering operation by reducing the steering force during low-speed driving or parking, and increasing the steering force during high-speed driving.

The driving assistance system 170 assists the driving operation of the vehicle 1, and performs a forward collision avoiding function, a lane departure warning function, a dead zone monitoring function, a rearward monitoring function, and the like.

The driving assistance system 170 may include a plurality of devices connected through communication. For example, the driving assistance system 170 may include Forward Collision Warning System (FCW) which detects a vehicle traveling in the same direction in front of the vehicle on the driving lane to avoid a collision with the preceding vehicle, Automatic Emergency Braking System (AEBS) which mitigates impact when collision with the preceding vehicle is inevitable, Adaptive Cruise Control (ACC) which detects vehicles travelling in the same direction in front of the vehicle on the driving lane and automatically accelerates/decelerates according to the speed of the preceding vehicle, Lane Departure Warning System (LDWS) which prevents departure from the driving lane, Lane Keeping Assist System (LKAS) which controls the vehicle to return to the current lane when it is determined that the vehicle departs from the lane, Blind Spot Detection (BSD) which provides a driver with information about vehicles located in blind spots, and Rear-end Collision Warning System (RCW) which detects a vehicle travelling in the same direction behind the vehicle on the driving lane to avoid a collision with the following vehicle.

The driving assistance system 170 may include a radar module 171 for detecting the positions of the preceding and following vehicles, and a camera module 172 for acquiring images of the preceding and following r vehicles. Specifically, the radar module 171 may be used in a device operating according to the position of the front and rear vehicle, such as Forward Collision Warning System (FCW), Advanced Emergency Braking System (AEBS), Adaptive Cruise Control (ACC), Blind Spot Detection (BSD) and Rear-end Collision Warning System (RCW). Also, the camera module 171 may be used in a device operating according to the preceding and following vehicles and an image of a road, such as a Lane Departure Warning System (LDWS) and Lane Keeping Assist System (LKAS).

for front and rear vehicles

[symbol]

Also, the voltage control system 180 according to the present disclosure may be used in the plurality of vehicle electronic devices 100 to perform a voltage control to enable an accurate operation of the vehicle electronic devices. In this regard, the vehicle sensors 200, which will be described below, may need to be used in the plurality of vehicle electronic devices 100 to enable the accurate operation.

The vehicle sensors 200 include an acceleration sensor 201, a yaw rate sensor 202, a steering angle sensor 203, a speed sensor 204, and the like that are included in the vehicle 1 to sense driving information of the vehicle 1.

The acceleration sensor 201 measures acceleration of the vehicle which may include a lateral acceleration sensor (not shown) and a longitudinal acceleration sensor (not shown).

The yaw rate sensor 202 may be installed on each wheel of the vehicle and may measure a yaw rate value in real time.

The steering angle sensor 203 measures the steering angle. The steering angle sensor 203 is mounted at a lower part of the steering wheel 60, and may detect a steering speed, a steering direction and a steering angle of the steering wheel.

The speed sensor 204 may be installed inside the wheel of the vehicle to detect the rotational speed of the vehicle wheel.

In particular, a wheel speed sensor (not shown) may be used as the speed sensor 204.

The configuration of the vehicle 1 has been described above.

Hereinafter, the configuration and operation of the voltage control system 180 included in the vehicle 1 will be described below.

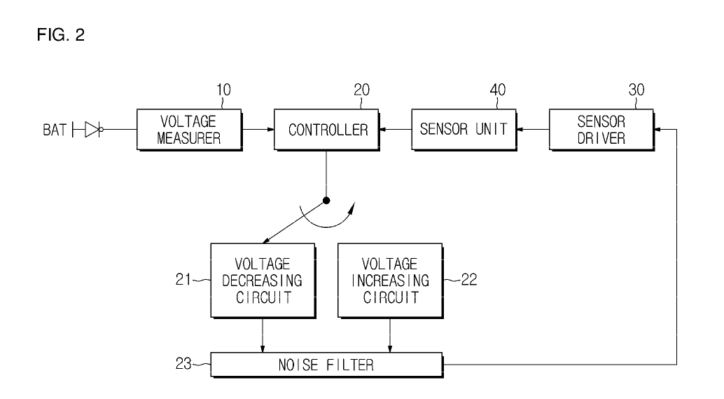

Referring to FIG. 2, the voltage control system 180 according to the present disclosure includes a voltage measurer 10 connected to a battery BAT included in the vehicle to measure a voltage of the battery BAT, a sensor driver 30 driving the vehicle sensors 200 included in the vehicle according to the measured voltage, and a controller 20 transmitting a voltage value required for the sensor to the sensor driver 30.

Also, a sensor unit 40 including the vehicle sensors 200 shown in FIG. 2 may transmit information about a rated voltage required by the vehicle sensors 200 to the controller 20.

Also, the controller 20 includes a voltage decreasing circuit 21 for decreasing a voltage value obtained from the battery connected to the voltage decreasing circuit 21 via a switch and a voltage increasing circuit 22 for increasing a voltage value obtained from the battery connected to the voltage increasing circuit 22 via a switch, and further includes a noise filter 23 for removing a noise signal.

Therefore, the controller 20 inputs a voltage obtained by removing the noise through the noise filter 23 to the sensor driver 30, so that the sensor operates at the corrected voltage value.

Specifically, the voltage measurer 10 measures the voltage of the battery BAT included in the vehicle 1.

Since the voltage of the Battery BAT may vary depending on the state of the vehicle, a constant voltage may be transmitted to each sensor by using the voltage increasing circuit 22 or the voltage decreasing circuit 21 according to the present disclosure based on the measured voltage value.

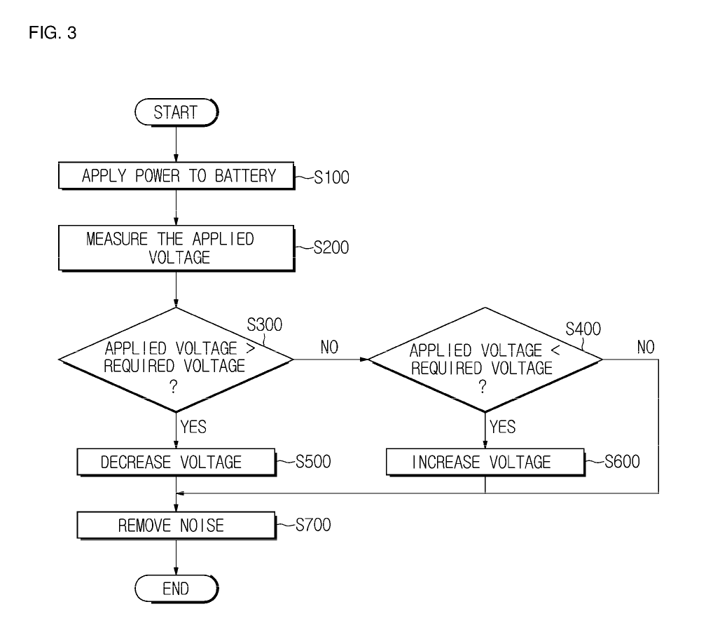

Specifically, referring to FIG. 3, the operation of the controller 20 according to the present disclosure may be described with reference to a flowchart showing a method of controlling a voltage.

First, power is applied to the battery (BAT) included in the vehicle 1 (100). Power may be applied to the battery (BAT) when the vehicle 1 including the voltage control system 180 according to the present disclosure is started.

At this time, the voltage control system 180 measures the applied voltage (200). By measuring the applied voltage of the battery (BAT) a correct voltage may be supplied to various sensors included in the vehicle 1 that operates on the voltage of the battery.

Therefore, when the measured value of the applied voltage of the battery is higher than a required voltage value required by any one of the plurality of devices to be supplied with the applied voltage (YES in operation 300), the switch is switched to operate the voltage decreasing unit 21 shown in FIG. 2 to decrease the applied voltage value to the required voltage value of the device.

Also, when the measured value of the applied voltage of the battery is lower than a required voltage value required by any one of the plurality of apparatuses to be supplied with the applied voltage (YES in operation 400), the switch is switched to the voltage increasing unit 22 shown in FIG. 2 to increase the applied voltage value.

In this case, an error may occur when the applied voltage is compared with the required voltage. Such an error may be removed in an operation of removing noise (700), so that the required voltage required by various sensors may be secured.

Accordingly, the voltage control system 180 removes the noise after decreasing the applied voltage to the required voltage value through the voltage decreasing circuit 21 or increasing the applied voltage to the required voltage value through the voltage increasing circuit 22 (700).

Thereafter, the sensor driver 30 applies a required voltage to which the noise is removed to the sensor so that the sensor may operate correctly.

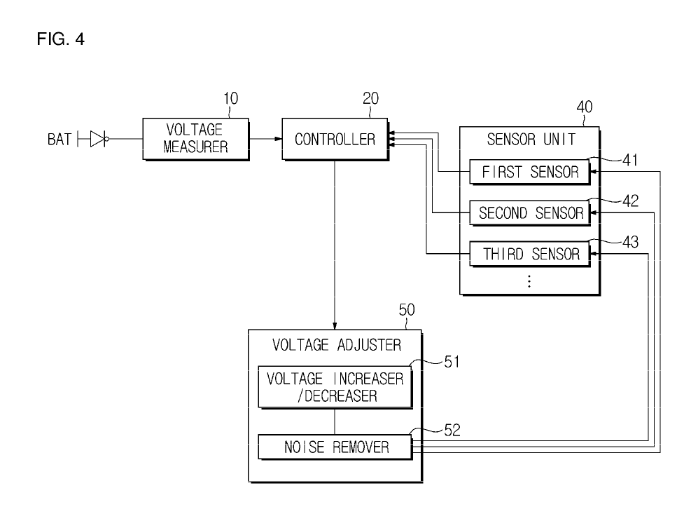

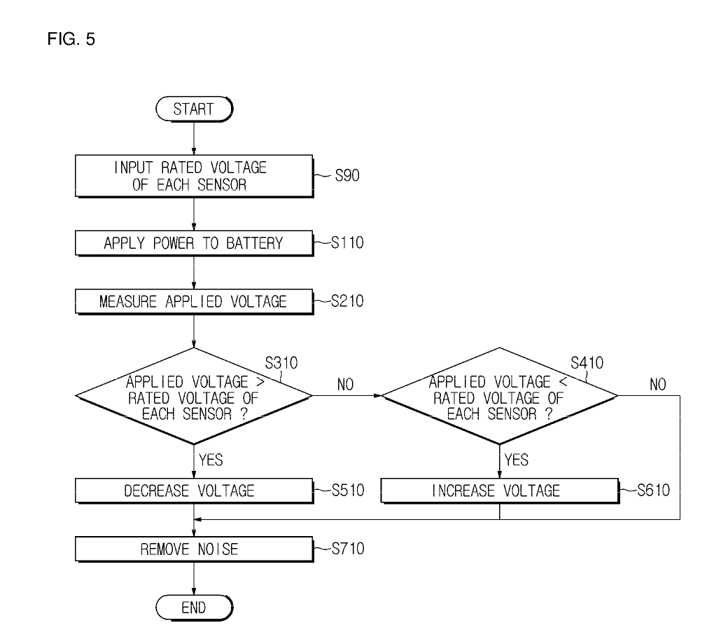

Next, FIG. 4, and FIG. 5 show another embodiment of the voltage control system of the vehicle according to the present disclosure. Specifically, FIG. 4 is a block diagram illustrating a voltage control system in accordance with a second embodiment of the present disclosure and FIG. 5 is a flowchart showing a voltage control method using in accordance with the second embodiment of the present disclosure.

Referring to FIG. 4, the voltage control system 180 according to the present disclosure includes a voltage measurer 10 connected to a battery (BAT) included in the vehicle to measure a voltage of the battery (BAT), a sensor unit 40 including the vehicle sensors 200 of FIG. 1, a voltage adjuster 50 to adjust a voltage value transmitted to the sensor unit 40, and a controller 20 to control overall operation of the voltage measurer 10, the sensor unit 40, and the voltage adjuster 50.

First, the voltage measurer 10 measures a value of a battery voltage outputted from the battery. An accurate measurement is required since the battery voltage rapidly changes according to an aging of the battery or a change in the number of sensors consuming power.

Next, the sensor unit 40 includes various sensors of the vehicle. In FIG. 4, the sensor unit 40 includes a first sensor 41, a second sensor 42, and a third sensor 43, but the sensors included in the sensor unit 40 according to the present disclosure is not limited thereto.

For example, the first sensor 41 may be a wheel speed sensor (not shown) to measure a vehicle speed of the vehicle.

In addition, various sensors of the vehicle included in the sensor unit 40 may be added or deleted according to environment settings of the vehicle. The sensor unit 40 may transmit a rated voltage-related information required by the first to third sensors 41 to 43 included in the sensor unit 40 to the controller 20.

The controller 20 controls the voltage adjuster 50 to output a correct voltage value to each sensor of the sensor unit 40 based on the respective pieces of rated voltage information of the various sensors acquired by the sensor unit 40.

Specifically, the voltage adjuster 50 includes a voltage increaser/decreaser 51 and a noise remover 52. That is, the voltage adjuster 50 includes the voltage increaser/decreaser 51 including a voltage decreasing circuit 21 for decreasing a voltage value obtained from the battery and a voltage increasing circuit 22 for increasing a voltage value obtained from the battery, and a noise remover 52 including a noise filter for removing a noise signal of a voltage value obtained via the voltage increaser/decreaser 51.

Therefore, the controller 20 supplies a voltage obtained by removing the noise signal through the noise filter 23 to each sensor of the sensor unit 40.

FIG. 5 is a flowchart of a voltage control method according to the present disclosure.

First, the voltage control system 180 receives e rated voltage information from each sensor included in the vehicle (90). For example, the controller 20 may receive rated voltages of the respective sensors from the first to third sensors 41 to 43 of the sensor unit 40.

Power is applied to the battery (BAT) included in the vehicle 1 (110). Power may be applied to the battery (BAT) when the vehicle 1 including the voltage control system 180 according to the present disclosure is started.

At this time, the voltage control system 180 measures the applied voltage (210).

The controller 20 measures the applied voltage inputted from the battery (BAT) such that each sensor included in the vehicle 1 which operates on the voltage of the battery inputs a correct sensor value.

Therefore, when the measured voltage of the battery is higher than a rated voltage value of any one of a plurality of devices to be supplied with the applied voltage (YES in operation 310), the voltage increaser/decreaser 51 in the voltage adjuster 50 operates to decrease the voltage to the required voltage value of the device.

Also, when the measured voltage of the battery is lower than a rated voltage value of any one of the plurality of devices to be supplied with the applied voltage (YES in operation 410), the voltage increaser/decreaser 51 in the voltage adjuster 50 operates to increase the voltage to the required voltage value of the device.

In this case, an error may occur when the applied voltage is compared with the rated voltage value. Such an error may be removed in an operation of removing noise (710) so that the rated voltage value required by various sensors may be secured.

Thereafter, the sensor driver 30 applies the required voltage obtained by removing noise to the sensor so that the sensor may operate correctly.

Although a few embodiments of the present disclosure have been shown and described, it would be appreciated by those skilled in the art that changes may be made in these embodiments without departing from the principles and spirit of the disclosure, the scope of which is defined in the claims and their equivalents.

As is apparent from the above description, the system and method for controlling a voltage accordance with one embodiment of the present disclosure can maintain the voltage supplied from the battery at a constant level, to secure a voltage value matching the rated voltage of the sensor.

Further, the system and method for controlling a voltage in accordance with one embodiment of the present disclosure can secure one control system for performing a control voltage which can be used in simultaneous manner in various sensors so that the production cost is reduced.

What is claimed is:

1. A voltage control system of a vehicle, the voltage control system comprising:
a battery voltage measurer configured to measure a voltage of a battery of a vehicle;
a sensor driver configured to supply a voltage applied from the battery to various sensors included in the vehicle; and
a controller configured to decrease or increase the voltage applied from the battery to secure a required voltage value required by the sensor driver.

2. The system of claim 1, wherein the controller further comprises:
a voltage decreasing circuit configured to decrease the voltage applied from the battery;
a voltage increasing circuit configured to increase the voltage applied from the battery; and
a noise filter configured to remove noise of a voltage passing through at least of the voltage increasing circuit and the voltage decreasing circuit.

3. A method of controlling a voltage of a vehicle, the method comprising:
measuring a voltage of a battery of the vehicle;
comparing the measured voltage of the battery with a required voltage required by a sensor; and
securing the required voltage by increasing or decreasing the voltage applied from the battery;

4. The method of claim 3, wherein the securing of the required voltage by increasing or decreasing the voltage applied from the battery includes
increasing the applied voltage when the applied voltage is higher than the required voltage, or decreasing the applied voltage when the applied voltage is lower than the required voltage; and
removing noise of at least of the decreased applied voltage and the increased applied voltage;

5. A system for controlling a voltage of a vehicle, the system comprising:
a battery;
a battery voltage measurer configured to measure a battery voltage of the battery of a vehicle;
at least one sensor included in the vehicle;
a controller configured to receive a rated voltage from the at least one sensor and decrease a battery voltage applied from the battery when a measurement of the applied battery voltage is higher than the rated voltage, and increase a battery voltage applied from the battery when a measurement of the applied battery voltage is lower than the rated voltage; and
a sensor driver configured to output the increased battery voltage or the decreased battery voltage to the at least one sensor.

6. The system of claim 5, wherein the controller further comprises:
a voltage decreasing circuit configured to decrease the battery voltage;
a voltage increasing circuit configured to increase the battery voltage; and
a noise filter configured to remove noise from a voltage passing through at least of the voltage increasing circuit and the voltage decreasing circuit.

7. A method for controlling a voltage of a vehicle, the method comprising:
measuring a battery voltage of a vehicle;
receiving a rated voltage from at least one sensor included in the vehicle;
decreasing the battery voltage when a measurement of the battery voltage is higher than the rated voltage and increasing the battery voltage when a measurement of the battery voltage is lower than the rated voltage; and
outputting the increased battery voltage or the decreased battery voltage to the at least one sensor.

8. The method of claim 7, wherein the decreasing or increasing of the battery voltage comprises removing noise from the decreased battery voltage or the increased battery voltage.
